(19) United States
(12) Patent Application Publication
(10) Pub. No.: US 2025/0268052 A1
(43) Pub. Date: Aug. 21, 2025

(54) Display Panel

(71) Applicant: LG Display Co., Ltd., Seoul (KR)

(72) Inventor: Sung Kyu Han, Paju-si (KR)

(21) Appl. No.: 19/019,148

(22) Filed: Jan. 13, 2025

(30) Foreign Application Priority Data
Feb. 20, 2024 (KR) 10-2024-0024255

(51) Int. Cl. H10K 59/35; H10K 59/126

(52) U.S. Cl. CPC H10K 59/353; H10K 59/126

(57) ABSTRACT

A display panel including a plurality of pixels is disclosed in the present disclosure. Each of the plurality of pixels may include a first light-emitting region surrounded by a first long side and a first short side parallel to each other and a first opposite side and a second opposite side facing each other, and implementing a first color; a second light-emitting region surrounded by a second long side and a second short side parallel to each other, and a third opposite side and a fourth opposite side facing each other, and implementing a second color; a third light-emitting region implementing a third color; and a plurality of light blocking patterns disposed to extend in a first direction, wherein the first long side and the second long side may be disposed to extend in a second direction intersecting the first direction.

### CROSS-REFERENCE TO RELATED APPLICATION

This application claims priority to and the benefit of Republic of Korea Patent Application No. 10-2024-0024255, filed on Feb. 20, 2024, which is hereby incorporated by reference in its entirety.

### BACKGROUND

### Field of the Invention

The present disclosure relates to a display panel.

### Discussion of Related Art

Electroluminescent display devices can be classified into inorganic light-emitting display devices and organic light-emitting display devices depending on the material of a light-emitting layer. An active-matrix type organic light-emitting display device includes an organic light-emitting diode (hereinafter, referred to as “OLED”) which emits light by itself, and has an advantage of a quick response time and high light-emitting efficiency, high brightness, and a wide viewing angle. The organic light-emitting diode (hereinafter, referred to as “OLED”) is formed in each pixel of the organic light-emitting display device. The organic light-emitting display device not only has a quick response time, and excellent light-emitting efficiency, excellent brightness, and an excellent viewing angle, but also has an excellent contrast ratio and color reproducibility as black gradations can be expressed as perfect black.

A display device disposed in front of a passenger's seat among display devices mounted in a vehicle provides a desired image to a passenger's seat user, but includes a blocking layer which blocks light emitted toward a driver so as not to disturb the driver when driving the vehicle. The blocking layer located on a display panel includes a light blocking pattern for controlling a viewing angle, and accordingly, a Moire phenomenon, which is an interference phenomenon between a light-emitting region structure of the display panel and the light blocking pattern of the blocking layer, may occur. Accordingly, since the performance of the display device can be lowered such as reducing the driver's visibility, a method of reducing the Moire phenomenon is required.

### SUMMARY

Embodiments of the present disclosure are directed to solving the above-described needs and/or problems according to the related art.

Additional features and embodiments will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described.

A display panel including a plurality of pixels, each of the plurality of pixels comprising: a first light-emitting region that is surrounded by a first long side and a first short side parallel to each other, and a first opposite side and a second opposite side facing each other and connecting both ends of the first lone side and both ends of the first short side, and implements a first color; a second light-emitting region that is surrounded by a second long side and a second short side parallel to each other, and a third opposite side and a fourth opposite side facing each other and connecting both ends of the second lone side and both ends of the first short side, and implements a second color; a third light-emitting region that is spaced apart from the first and second light-emitting regions and implements a third color; and a plurality of light blocking patterns disposed to extend in a first direction to overlap the first to third light-emitting regions, wherein the first long side and the second long side are disposed to extend in a second direction intersecting the first direction.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a block diagram illustrating a display device according to one embodiment of the present disclosure;

FIG. 2 is a schematic cross-sectional view illustrating the display device according to one embodiment of the present disclosure;

FIG. 3 is a schematic cross-sectional view illustrating the display device according to one embodiment of the present disclosure;

FIG. 4 is a simulation graph illustrating a brightness profile of a display panel according to a viewing angle when a blocking layer is not included;

FIG. 5 is a simulation graph illustrating a brightness profile of the display panel according to the viewing angle when the blocking layer is included;

FIG. 6 is a view for describing the Moire phenomenon;

FIG. 7 is a plan view illustrating the pixel disposition of the display panel according to one embodiment of the present disclosure;

FIG. 8 is a partially enlarged view illustrating P region in FIG. 7 according to one embodiment of the present disclosure;

FIG. 9 is a view for describing a reduction of the Moire phenomenon;

FIG. 10 is a view for describing a reduction of the Moire phenomenon;

FIG. 11 is a first modified example of FIG. 8 according to one embodiment of the present disclosure;

FIG. 12 is a second modified example of FIG. 8 according to one embodiment of the present disclosure; and

FIG. 13 is a view illustrating a portion of a vehicle to which the display device according to one embodiment of the present disclosure is applied.

### DETAILED DESCRIPTION

Advantages and features of the present disclosure disclosed in the present disclosure, and methods of achieving them will become apparent with reference to the following embodiments, which are described in detail, in conjunction with the accompanying drawings. The present disclosure is not limited to the embodiments to be described below and may be implemented in various different forms, the embodiments are only provided to completely disclose the present disclosure and completely convey the scope of the present disclosure to those skilled in the art, and the present disclosure is defined only by the scope of the claims.

In describing the present disclosure, when it is determined that a detailed description of related known technology may unnecessarily obscure the gist of the present disclosure, the detailed description thereof will be omitted.

When ‘providing,’ ‘including,’ ‘having,’ ‘comprising,’ and the like mentioned in the present disclosure are used, other parts may be added unless ‘only’ is used. A case where a component is expressed in a singular form includes a plural form unless explicitly stated otherwise.

When a positional relationship or an interconnected relationship between two components such as ‘on,’ ‘above,’ ‘under,’ ‘next to,’ ‘connect or couple,’ ‘crossing or intersecting,’ and the like is described, one or more other components may be interposed between the components unless ‘immediately’ or ‘directly’ is mentioned.

When a temporal relationship such as ‘after,’ ‘following,’ ‘next,’ ‘before,’, and the like is described, the temporal relationship may not be continuous on a time axis unless ‘immediately’ or ‘directly’ is used.

First, second, and the like may be used to distinguish components, but the functions or structures of these components are not limited by ordinal numbers in front of the components or component names.

The following embodiments may be partially or entirely coupled to or combined with each other, and technically, various types of interconnections and driving are possible. The embodiments may be implemented independently of each other or may be implemented together in an associated relationship.

Terms (including technical and scientific terms) used in the embodiments of the present disclosure may be interpreted as meanings which may be generally understood by those skilled in the art unless explicitly specifically defined and described, and meanings of commonly used terms such as terms defined in a dictionary may be interpreted in consideration of contextual meanings of the related technology.

In a display device according to the present disclosure, a pixel circuit and a gate driving circuit may include a plurality of transistors. The transistor may be an oxide thin film transistor (TFT) including an oxide semiconductor or a low temperature poly silicon (LTPS) TFT including LTPS.

The transistor is a three-electrode element including a gate, a source, and a drain. The source is an electrode which supplies charge carriers to the transistor. In the transistor, the charge carriers start to flow from the source. The drain is an electrode through which the charge carriers exit the transistor. In the transistor, the charge carriers flow from the source to the drain.

In the case of an n-channel transistor, since the charge carriers are electrons, a source voltage has a lower voltage than a drain voltage so that electrons may flow from the source to the drain. In the n-channel transistor, current flows in a direction from the drain to the source. In the case of a p-channel transistor, since the charge carriers are holes, the source voltage is higher than the drain voltage so that holes may flow from the source to the drain. In the p-channel transistor, since holes flow from the source to the drain, current flows from the source to the drain. It should be noted that the source and drain of the transistor are not fixed. For example, the source and drain may be changed depending on the applied voltage. Accordingly, the present disclosure is not limited by the source and drain of the transistor. In the following description, the source and drain of the transistor will be referred to as first and second electrodes.

A gate signal may swing between a gate on voltage and a gate off voltage. The transistor is turned on in response to the gate on voltage, but is turned off in response to the gate off voltage. In the case of the n-channel transistor, the gate on voltage may be a gate high voltage VGH, and the gate off voltage may be a gate low voltage VGL. In the case of the p-channel transistor, the gate on voltage may be the gate low voltage VGL, and the gate off voltage may be the gate high voltage VGH.

Hereinafter, embodiments of the present disclosure will be described in detail with reference to the accompanying drawings.

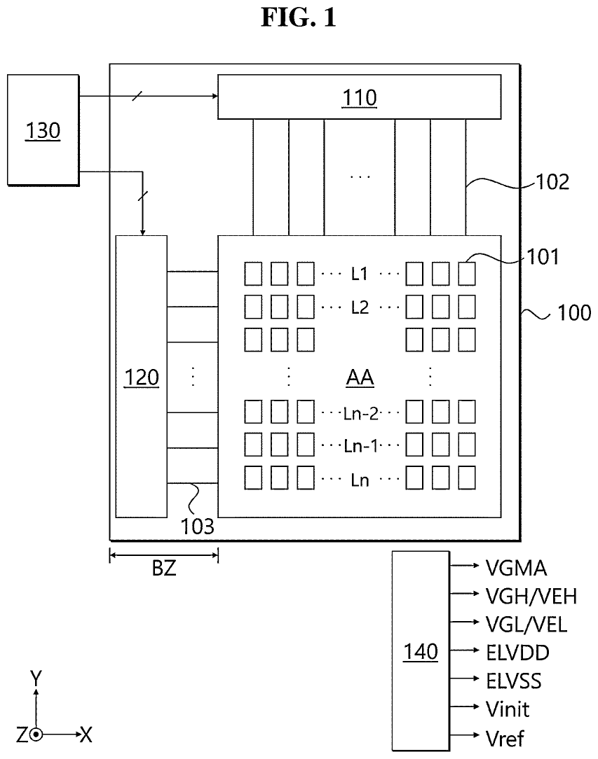

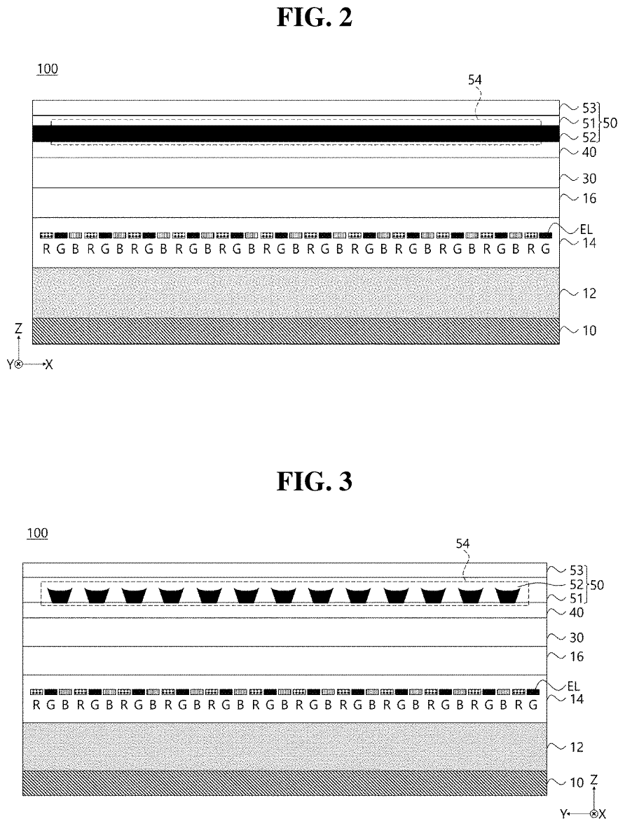

FIG. 1 is a block diagram illustrating a display device according to one embodiment of the present disclosure. FIGS. 2 and 3 are schematic cross-sectional views illustrating the display device according to one embodiment of the present disclosure.

Referring to FIGS. 1, 2, and 3, the display device may include a display panel 100, display panel drivers 110 and 120 for writing pixel data to pixels of the display panel 100, and a power unit 140 (e.g., a circuit) for generating power required to drive the pixels and the display panel drivers 110 and 120.

The display panel 100 may be a panel with a rectangular structure having a length in an X-axis direction, a width in a Y-axis direction, and a thickness in a Z-axis direction, but is not limited thereto. The display panel 100 may include a pixel array AA which displays an input image on a screen. The pixel array AA may include a plurality of data lines 102, a plurality of gate lines 103 intersecting the data lines 102, and a plurality of pixels 101 disposed in a matrix form.

The display panel 100 may further include power lines connected to the pixels 101 in common. The power lines may supply a constant voltage required to drive the pixels 101 to the pixels 101. For example, the display panel 100 may include a VDD line to which a pixel driving voltage ELVDD is applied, and a VSS line to which a pixel reference voltage ELVSS is applied. The power lines may further include a REF line to which a reference voltage Vref is applied and an INIT line to which an initialization voltage Vinit is applied.

A cross-sectional structure of the display panel 100 may include a circuit layer 12, a light-emitting element layer 14, and an encapsulation layer 16 stacked on a substrate 10.

The circuit layer 12 may include a TFT array including a pixel circuit connected to lines such as the data lines, the gate lines, the power lines, and the like, a gate driver 120, and the like. The lines and circuit elements of the circuit layer 12 may include a plurality of insulating layers, two or more metal layers separated by the insulating layers therebetween, and an active layer including a semiconductor material.

The light-emitting element layer 14 may include a light-emitting element EL driven by the pixel circuit. The light-emitting element EL may include a light-emitting element which implements red R, a light-emitting element which implements green G, and a light-emitting element which implements blue B.

The encapsulation layer 16 may cover the light-emitting element layer 14 to seal the circuit layer 12 and the light-emitting element layer 14. The encapsulation layer 16 may also have a multi-insulating film structure in which organic films and inorganic films are alternately stacked. The inorganic film may block the penetration of moisture or oxygen. The organic film may flatten a surface of the inorganic film. When the organic films and the inorganic films are stacked in multiple layers, since a movement path of moisture or oxygen is longer compared to a single layer, the penetration of moisture and oxygen which affect the light-emitting element layer 14 may be effectively blocked.

An optical function member 30 may include a phase retarder and a polarizer. The phase retarder may be a film type or a liquid crystal coating type. The polarizer may also be a film type or a liquid crystal coating type. The film type may include a stretchable synthetic resin film, and the liquid crystal coating type may include liquid crystals arranged in a predetermined array.

In another embodiment, the optical function member 30 may include a black matrix and color filters. The color filters may be arranged in consideration of the color of light emitted from each of the pixels 101. Each of the color filters may include a red, green, or blue pigment or dye. Alternatively, each of the color filters may further include quantum dots other than the above-described pigment or dye. Alternatively, some of the color filters may not include the above-described pigments or dyes and may include scattering particles such as titanium oxide.

An adhesive portion 40 may connect the optical function member 30 and a blocking portion 50 to each other. The adhesive portion 40 may include an optically clear adhesive (OCA).

The blocking portion 50 may include a base layer 51, a blocking layer 52, and a protective layer 53. The base layer 51 may include a transparent resin for a nano-implant. For example, the base layer 51 may include polyethylene methyl methacrylate, a photocurable resin, and the like.

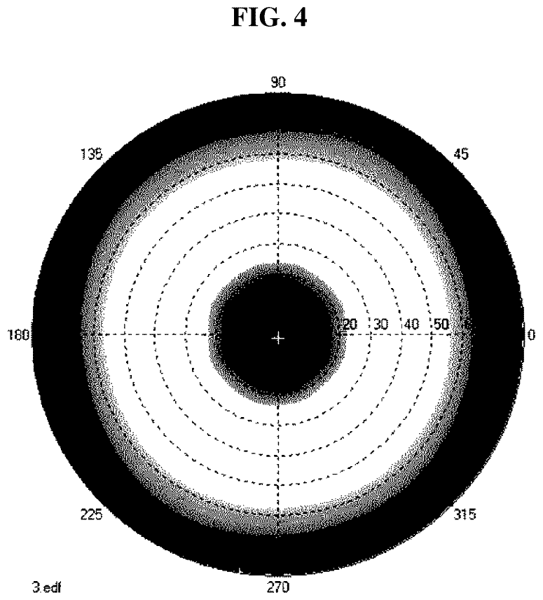

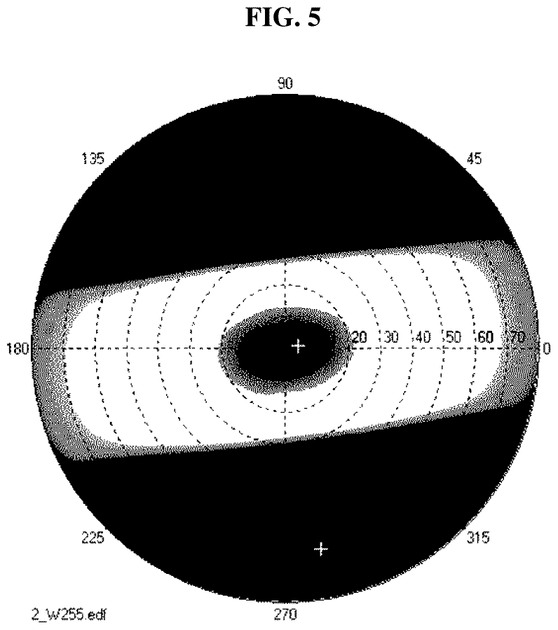

The blocking layer 52 may be formed to be inserted into the base layer 51. The blocking layer 52 may be formed of an opaque material to block external light or light from the display panel 100 from being transmitted to the outside. A plurality of blocking layers 52 may be provided and arranged to be spaced apart from each other so as to form a certain angle in the Z-axis direction with respect to a plane formed by a display region. The form in which the blocking layer 52 is formed may form a light blocking pattern 54. Accordingly, the blocking layer 52 may prevent light of the display region from being diffused. Referring to FIGS. 4 and 5, it is confirmed that a light diffusion degree is controlled depending on the presence or absence of the blocking layer 52. The blocking layer 52 may be formed in the form of ink and may be formed to be hardened on the base layer 51. An end of the blocking layer 52 adjacent to an inner surface of the base layer 51 (for example, an end disposed in the Z-axis direction) among the ends of the blocking layers 52 may be concavely formed. Here, for example, as shown in FIG. 3, the inner surface of the base layer 51 is adjacent to the protective layer 53. The end of the blocking layer 52 may be formed so as to be introduced into the base layer 51. A longitudinal direction (for example, the Y-axis direction) of the blocking layer 52 may be parallel to one side of the display panel 100 or may have a constant angle when the display panel 100 is formed in a quadrangular shape. In one embodiment, the light blocking pattern 54 may include a reverse-tapered shape in the thickness direction (for example, the Z-axis direction) of the display panel 100. Accordingly, since light directed in a specific direction may be blocked, a user's viewing angle may be limited. Further, a user may not recognize a reflection phenomenon caused by light emission from the display panel 100, and the visibility of the display panel 100 may be enhanced.

The protective layer 53 may be disposed at the outside to protect the blocking layer 52 and the display panel 100 from an external impact. The protective layer 53 may include polycarbonate.

The pixel array AA may include a plurality of pixel lines L1 to Ln. Each of the pixel lines L1 to Ln may include one line of pixels disposed along a line direction (the X-axis direction) in the pixel array AA of the display panel 100. The pixels disposed in one pixel line may share gate lines 103. The sub-pixels disposed in a column direction (Y) along a data line direction may share the same data line 102. One horizontal period is the time acquired by dividing one frame period by the total number of pixel lines L1 to Ln.

Each of the pixels 101 may be divided into a red sub-pixel, a green sub-pixel, and a blue sub-pixel to implement a color. Each of the pixels may further include a white sub-pixel.

The power unit 140 may generate a direct current (DC) voltage (or a constant voltage) required to drive the pixel array AA of the display panel 100 and the display panel driver using a DC-DC converter. The DC-DC converter may include a charge pump, a regulator, a buck converter, a boost converter, and the like. The power unit 140 may adjust the level of a DC input voltage applied from a host system (not shown) to generate a DC voltage (or a constant voltage) such as a gamma reference voltage VGMA, the gate on voltage VGH, the gate off voltage VGL, the pixel driving voltage ELVDD, the pixel reference voltage ELVSS, the initialization voltage Vinit, and the reference voltage Vref.

The display panel driver may write pixel data of the input image to the pixels of the display panel 100 under control of a timing controller 130.

The display panel driver may include a data driver 110 and a gate driver 120.

The data driver 110 may receive the pixel data of the input image received as a digital signal from the timing controller 130 and output a data voltage. The data driver 110 may convert the pixel data of the input image into a gamma compensation voltage for each frame period using a digital to analog converter (DAC) and generate a data voltage Vdata. The gamma reference voltage VGMA may be divided into a gamma compensation voltage for each gradation through a voltage divider circuit. The gamma compensation voltage for each gradation may be provided to the DAC of the data driver 110. The data voltage Vdata may be output through an output buffer from each channel of the data driver 110.

The gate driver 120 may be implemented as a gate in panel (GIP) circuit formed in the circuit layer 12 on the display panel 100 along with a TFT array and lines of the pixel array AA. The gate driver 120 may be disposed in a bezel region which is a non-display region of the display panel 100 or may be disposed to be distributed in the pixel array AA where the input image is reproduced. The gate driver 120 may sequentially output gate signals to the gate lines 103 under control of the timing controller 130. The gate driver 120 may sequentially supply the signals to the gate lines 103 by shifting the gate signals using a shift register. The gate signal may include various gate pulses such as a scan pulse, a light emission control pulse (hereinafter, referred to as a “pulse”), an initialization pulse, a sensing pulse, and the like.

The timing controller 130 may receive digital video data DATA of the input image and a timing signal synchronized with the digital video data DATA from the host system.

The host system may be any one of a television (TV) system, a tablet computer, a notebook computer, a navigation system, a personal computer (PC), a home theater system, a mobile device, a wearable device, and a vehicle system. The host system may scale an image signal from a video source to be suitable for a resolution of the display panel 100 and transmit the image signal to the timing controller 130 along with the timing signal.

The timing controller 130 may generate a data timing control signal for controlling an operation timing of the data driver 110 and a gate timing control signal for controlling an operation timing of the gate driver 120 based on timing signals Vsync, Hsync, and DE received from the host system. The timing controller 130 may control an operation timing of the display panel driver to synchronize the data driver 110 and the gate driver 120.

The gate timing control signal generated from the timing controller 130 may be input to the shift register of the gate driver 120 through a level shifter (not shown). The level shifter may receive the gate timing control signal and generate a start pulse and a shift clock to provide the start pulse and the shift clock to the shift register of the gate driver 120.

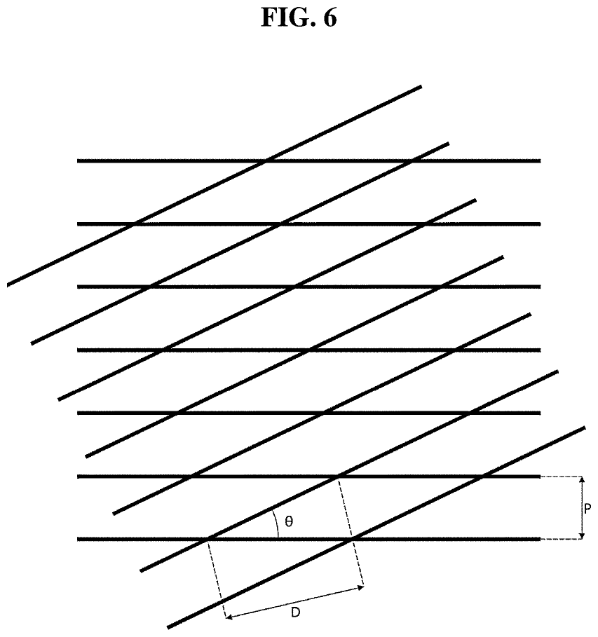

FIG. 6 is a view for describing the Moire phenomenon.

Referring to FIG. 6, two patterns having constant pitches P may be formed while having an intersection angle θ. The pitches P of the two patterns may be different from each other, but for convenience of description, it is assumed and described that the pitches P are substantially the same.

When the pitches P are the same, the Moire period D may be described by the following equation.

D=Pcos(θ/2)/sin(θ)=P/2sin(θ/2) [Equation 1]

Referring to the Equation 1, the period D at which the Moire phenomenon appears may be determined by the intersection angle θ and the pitch P. Even when the pitches P of the two patterns are different, the period D at which the Moire phenomenon appears is affected by the intersection angle θ and the pitch P.

In order to reduce the probability of the Moire phenomenon being recognized, since the period D should be reduced, the intersection angle θ should be increased or the pitch P should be reduced.

In the display panel according to the embodiment of the present disclosure, each of the two patterns may correspond to the above-described light blocking pattern 54 and the pixel gap or sub-pixel pitch to be described below.

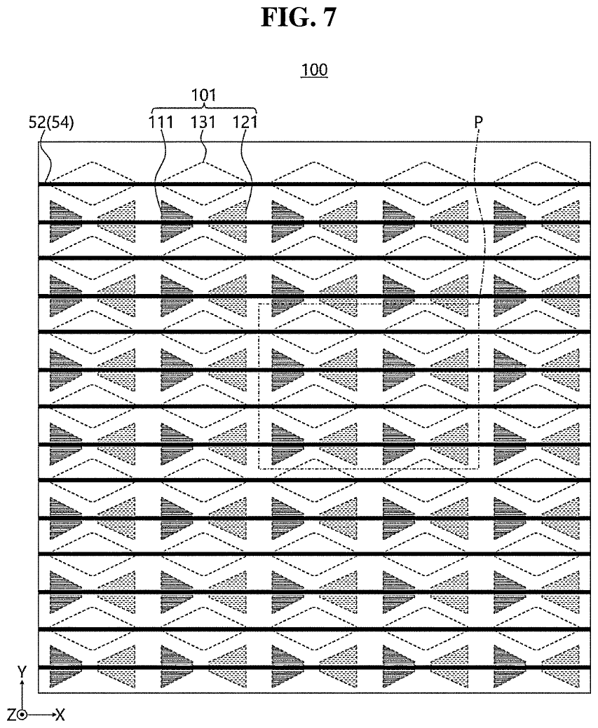

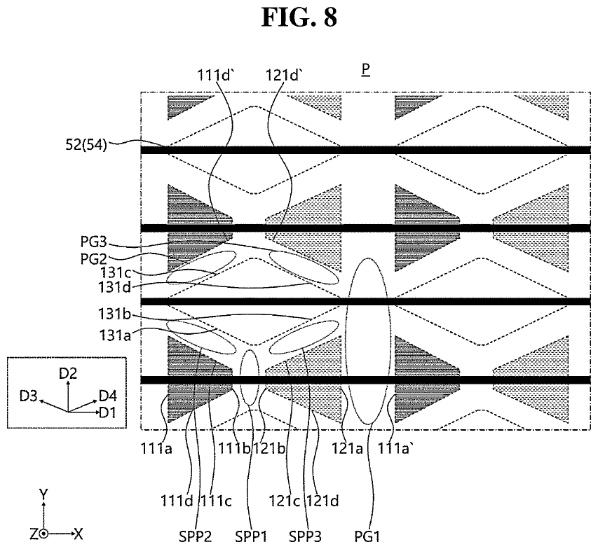

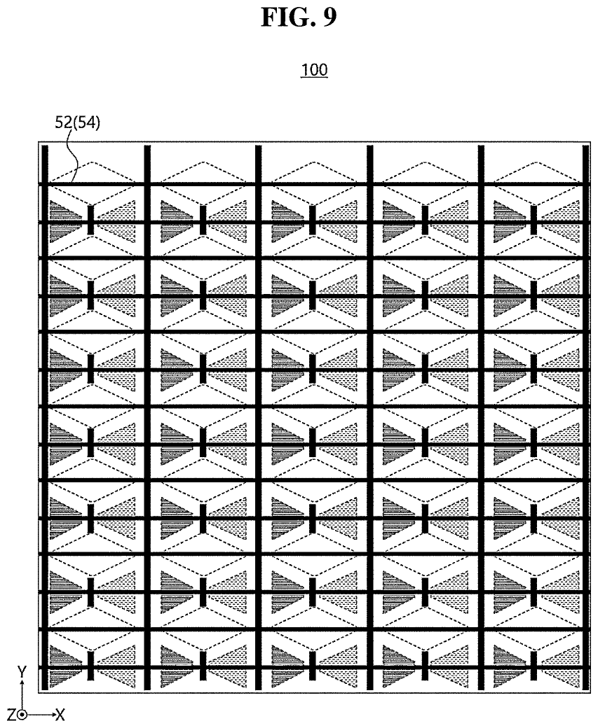

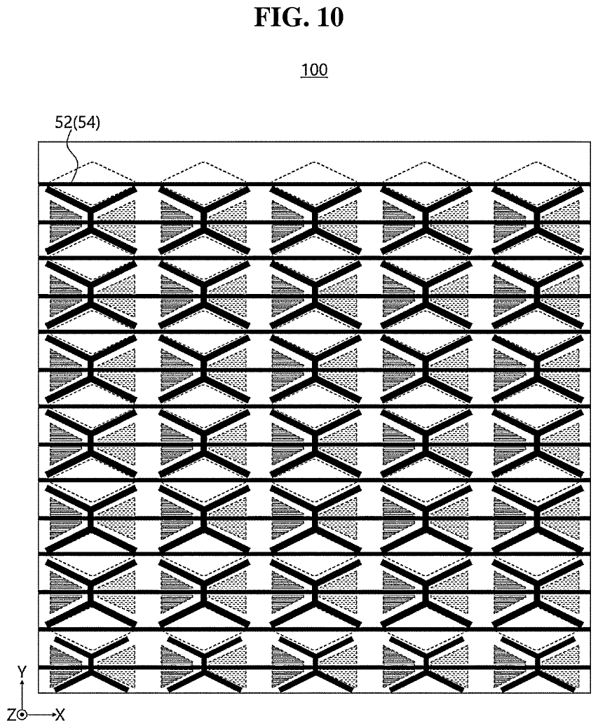

FIG. 7 is a plan view illustrating the pixel disposition of the display panel according to one embodiment of the present disclosure. FIG. 8 is a partially enlarged view illustrating P region in FIG. 7 according to one embodiment of the present disclosure. FIG. 9 is a view for describing a reduction of the Moire phenomenon. FIG. 10 is a view for describing a reduction of the Moire phenomenon.

Referring to FIGS. 7 and 8, the display panel 100 may include the plurality of pixels 101. Each pixel 101 may include a first light-emitting region 111, a second light-emitting region 121, and a third light-emitting region 131. The first light-emitting region 111 may implement a first color, the second light-emitting region 121 may implement a second color, and the third light-emitting region 131 may implement a third color. The first to third colors may be any one selected from the group consisting of red, green, and blue so as not to overlap each other. In one embodiment, the first light-emitting region 111, the second light-emitting region 121, and the third light-emitting region 131 may correspond to a first sub-pixel, a second sub-pixel, and a third sub-pixel, respectively.

Referring to the partially enlarged view shown in FIG. 8, the pixel 101 may include the first to third light-emitting regions 111, 121, and 131 and a first sub-pixel pitch region SPP1, a second sub-pixel pitch region SPP2, and a third sub-pixel pitch region SPP3 disposed between the first to third light-emitting regions 111, 121, and 131. The display panel 100 may include a first pixel gap region PG1, a second pixel gap region PG2, and a third pixel gap region PG3 disposed between the plurality of pixels 101.

The first to third sub-pixel pitch regions SPP1, SPP2, and SPP3 and the first to third pixel gap regions PG1, PG2, and PG3 may include the above-described black matrix and a bank layer disposed to surround ends of the first to third light-emitting regions 111, 121, and 131. Accordingly, the first to third sub-pixel pitch regions SPP1, SPP2, and SPP3 and the first to third pixel gap regions PG1, PG2, and PG3 may form a second pattern on a plan view. Due to the second pattern, a user of the display device may recognize a constant stripe pattern.

The above-described blocking portion may be disposed on the plurality of pixels 101. The blocking portion may include the base layer, the blocking layer 52, and the protective layer as described above, but the base layer and the protective layer are omitted in the drawing. The blocking layer 52 formed in the manner described above may form the light blocking pattern 54 as described above. The light blocking pattern 54 may correspond to the first pattern.

As the display panel according to one embodiment of the present disclosure includes the blocking layer 52, light emitted from the display panel may be prevented from being directed to another transparent window (for example, a vehicle window) disposed adjacent to a position where the display device is disposed. The blocking layer 52 may limit a user's viewing angle by blocking light directed in a specific direction. The specific direction may be, for example, an up and down direction including the Y-axis direction. Accordingly, the user may not recognize the reflection phenomenon caused by the light emission from the display panel 100, and the visibility of the display panel 100 may be enhanced. Since the amount of light reflected from the display panel 100 to another transparent window is limited, images may not be seen when formed at positions other than the display device.

The display panel 100 according to one embodiment of the present disclosure may prevent the Moire phenomenon which may occur while the viewing angle is limited by including the blocking layer 52.

For example, since the first pattern formed by the light blocking pattern 54 and the second pattern formed by the pixel gap or sub-pixel pitch may interfere with each other, the Moire phenomenon may occur. Conventionally, in order to prevent the Moire phenomenon caused by the blocking layer 52 for limiting the viewing angle along with the pixel gap or sub-pixel pitch, a disposition direction of the blocking layer 52 was slightly offset in a direction forming an angle of about 5 to 10 degrees with respect to the X-axis direction. However, in this case, apart from the advantage in that the viewing angle is limited, there was a problem of the brightness value of the display panel being lowered.

The display panel according to the present disclosure may have an advantage in that the Moire phenomenon is prevented or at least reduced and the brightness value of the display panel 100 is maintained while having the advantage of limiting the viewing angle by maintaining the disposition direction of the blocking layer 52 parallel to the X-axis direction. The intersection angle between the second pattern and the first pattern may be increased, and accordingly, the period of the Moire phenomenon may be reduced and the visibility of the display panel 100 may be enhanced.

Referring to the partially enlarged view again, the light blocking pattern 54 may be disposed to extend in a first direction D1 (for example, the X-axis direction).

The first light-emitting region 111 may be a region surrounded by a first long side 111a and a first short side 111b which are parallel to each other and a first opposite side 111c and a second opposite side 111d facing each other. In the present disclosure, “the surrounded region” does not necessarily need to be a region surrounded by consecutive sides or curves. For example, the first light-emitting region 111 is surrounded by the first long side 111a and the first short side 111b and the first opposite side 111c and second opposite side 111d facing each other, but does not necessarily need to be formed in a quadrangular shape and may have a shape surrounded by additional curves or sides.

The second light-emitting region 121 may be a region surrounded by a second long side 121a and a second short side 121b which are parallel to each other, and a third opposite side 121c and a fourth opposite side 121d facing each other.

The third light-emitting region 131 may be a region surrounded by a fifth opposite side 131a disposed to face the first opposite side 111c, a sixth opposite side 131b disposed to face the third opposite side 121c, a seventh opposite side 131c disposed to face the sixth opposite side 131b, and an eighth opposite side 131d disposed to face the fifth opposite side 131a. The third light-emitting region 131 may substantially have a rhombus shape, but is not limited thereto. Lengths of the fifth to eighth opposite sides 131a, 131b, 131c, and 131d may be substantially the same, but are not limited thereto. The fifth opposite side 131a and the first opposite side 111c may be parallel to each other. The fifth opposite side 131a and the eighth opposite side 131d may be parallel to each other. The sixth opposite side 131b and the third opposite side 121c may be parallel to each other. The sixth opposite side 131b and the seventh opposite side 131c may be parallel to each other. The seventh opposite side 131c and the second opposite side 111d may be parallel to each other. The eighth opposite side 131d and the fourth opposite side 121d may be parallel to each other.

In one embodiment, the third light-emitting region 131 may have a larger size than the first light-emitting region 111 or the second light-emitting region 121. The first to third colors implemented by the first to third light-emitting regions 111, 121, and 131 are selected from the group consisting of the red, the green, and the blue, but the third color may be blue in consideration of the lifespan and the like of the light-emitting element.

The first light-emitting region 111 may have a larger size than the second light-emitting region 121. In consideration of the lifespan and the like of the light-emitting element, the first color may be green and the second color may be red.

As described above, peripheral portions of the first to third light-emitting regions 111, 121, and 131 may include a bank layer or a pixel definition layer. The bank layer may be disposed on the first long side 111a, the second long side 121a, the first short side 111b, the second short side 121b, and the first to eighth opposite sides 111c, 111d, 121c, 121d, 131a, 131b, 131c, and 131d.

The first long side 111a, the second long side 121a, the first short side 111b, and the second short side 121b may be disposed to extend in a second direction D2 (for example, the Y-axis direction). The first opposite side 111c and the fourth opposite side 121d may be disposed to extend in a third direction D3. The second opposite side 111d and the third opposite side 121c may be disposed to extend in a fourth direction D4.

In the present disclosure, an intersection angle of specific directions may be defined only as greater than or equal to 0 degrees and less than or equal to 90 degrees. In one embodiment, an intersection angle of the first direction D1 and the second direction D2 may be greater than 0 degrees and less than or equal to 90 degrees. Preferably, the intersection angle of the first direction D1 and the second direction D2 may be 90 degrees and orthogonal to each other. An intersection angle of the third direction D3 and the second direction D2 may be greater than 0 degrees and less than 90 degrees. An intersection angle of the third direction D3 and the first direction D1 may be greater than 0 degrees and less than 90 degrees. An intersection angle of the third direction D3 and the second direction D2 may be substantially the same as the intersection angle of the fourth direction D4 and the second direction D2, but is not limited thereto. The intersection angle of the third direction D3 and the first direction D1 may be substantially the same as the intersection angle of the fourth direction D4 and the first direction D1, but is not limited thereto.

The display panel 100 may include a first pixel gap region PG1 defined by a first long side 111a′ included in one pixel and a second long side 121a included in another pixel. Since the first long side 111a′ and the second long side 121a are disposed to extend in the second direction D2, the first pixel gap region PG1 may be disposed to extend in the second direction D2.

The first pixel gap region PG1 may form a second pattern. In the display panel according to one embodiment of the present disclosure, the intersection angle between the second pattern formed by the first pixel gap region PG1 extending in the second direction D2 and the first pattern formed by the light blocking pattern 54 extending in the first direction D1 may be greater than 0 degrees. In one embodiment, the intersection angle may be greater than 30 degrees or greater than 45 degrees. More preferably, the intersection angle of the second pattern and the first pattern may be 90 degrees and may be orthogonal to each other. Accordingly, the period of the Moire phenomenon may be reduced, and a window reflection phenomenon may be reduced while the brightness of the display panel is maintained (see FIG. 9).

Any one pixel may include a first sub-pixel pitch region SPP1 surrounded by a first short side 111b and a second short side 121b. Since the first short side 111b and the second short side 121b are disposed to extend in the second direction D2, the first sub-pixel pitch region SPP1 may be disposed to extend in the second direction D2.

The first sub-pixel pitch region SPP1 may form a second pattern. In the display panel according to one embodiment of the present disclosure, the intersection angle between the second pattern formed by the first sub-pixel pitch region SPP1 extending in the second direction D2 and the first pattern formed by the light blocking pattern 54 extending in the first direction D1 may be greater than 0 degrees. In one embodiment, the intersection angle may be greater than 30 degrees or greater than 45 degrees. More preferably, the intersection angle of the second pattern and the first pattern may be 90 degrees and may be orthogonal to each other. Accordingly, the period of the Moire phenomenon may be reduced, and the window reflection phenomenon may be reduced while the brightness of the display panel is maintained (see FIG. 9).

Any one pixel may include a second sub-pixel pitch region SPP2 surrounded by a first opposite side 111c and a fifth opposite side 131a. Any one pixel may include a third sub-pixel pitch region SPP3 surrounded by a third opposite side 121c and a sixth opposite side 131b. The second sub-pixel pitch region SPP2 may be disposed to extend in the third direction D3. The third sub-pixel pitch region SPP3 may be disposed to extend in the fourth direction D4.

The second sub-pixel pitch region SPP2 may form a second pattern. The third sub-pixel pitch region SPP3 may also form a second pattern. In the display panel according to one embodiment of the present disclosure, the intersection angle between the second pattern formed by the second sub-pixel pitch region SPP2 or third sub-pixel pitch region SPP3 extending in the third direction D3 or fourth direction D4 and the first pattern formed by the light blocking pattern 54 extending in the first direction D1 may be greater than 0 degrees. In one embodiment, the intersection angle may be greater than 30 degrees or greater than 45 degrees. Accordingly, the period of the Moire phenomenon may be reduced, and the window reflection phenomenon may be reduced while the brightness of the display panel is maintained (see FIG. 10).

The display panel 100 may include a second pixel gap region PG2 surrounded by a seventh opposite side 131c included in one pixel and a second opposite side 111d′ included in another pixel. The display panel 100 may include a third pixel gap region PG3 surrounded by an eighth opposite side 131d included in one pixel and a fourth opposite side 121d′ included in another pixel. The second pixel gap region PG2 may be disposed to extend in the fourth direction D4 parallel to the third sub-pixel pitch region SPP3. The third pixel gap region PG3 may be disposed to extend in the third direction D3 parallel to the second sub-pixel pitch region SPP2.

The second pixel gap region PG2 may form a second pattern. The third pixel gap region PG3 may also form a second pattern. In the display panel according to one embodiment of the present disclosure, the intersection angle between the second pattern formed by the second pixel gap region PG2 extending in the fourth direction D4 or third pixel gap region PG3 extending in the third direction D3 and the first pattern formed by the light blocking pattern 54 extending in the first direction D1 may be greater than 0 degrees. In one embodiment, the intersection angle may be greater than 30 degrees or greater than 45 degrees. Accordingly, the period of the Moire phenomenon may be reduced, and the window reflection phenomenon may be reduced while the brightness of the display panel is maintained (see FIG. 10).

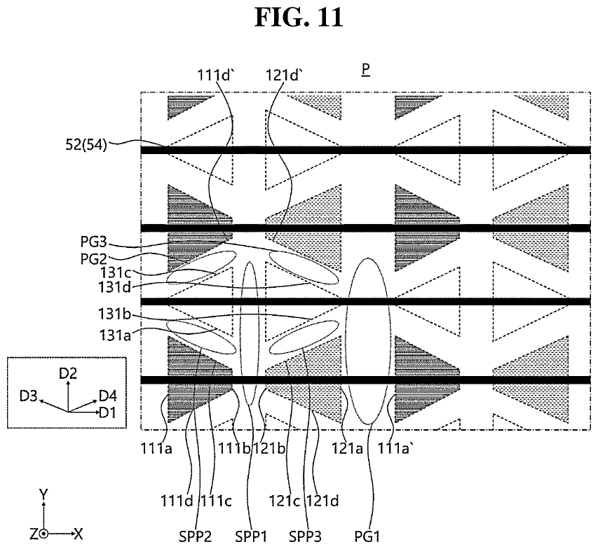

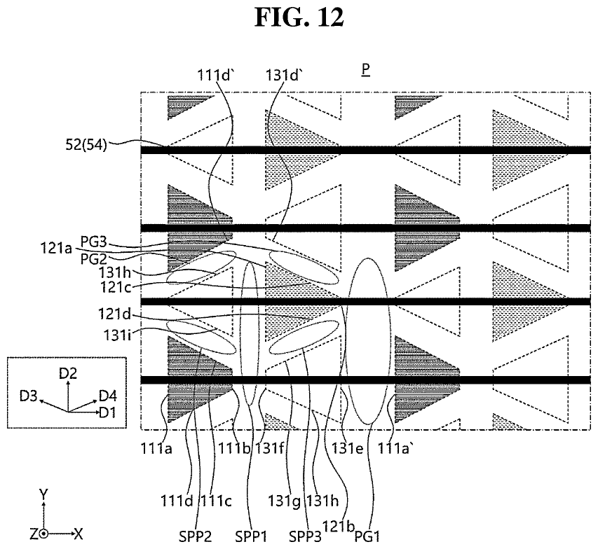

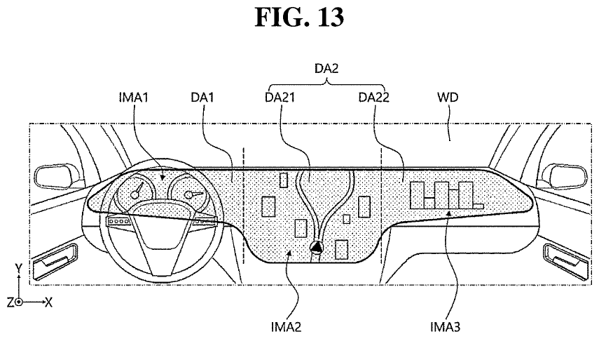

FIG. 11 is a first modified example of FIG. 8 according to one embodiment. FIG. 12 is a second modified example of FIG. 8 according to one embodiment. The same reference numerals are given to configurations having substantially the same function as in the above-described embodiment, and detailed descriptions thereof will be omitted.

Referring to FIG. 11, the third light-emitting region 131 may include a fourth light-emitting region surrounded by the fifth opposite side 131a and the seventh opposite side 131c, and a fifth light-emitting region surrounded by the sixth opposite side 131b and the eighth opposite side 131d. The fourth light-emitting region and the fifth light-emitting region may implement the third color. The first sub-pixel pitch region SPP1 may extend in the second direction D2. Accordingly, the color reproducibility of the display panel may be enhanced, and the visibility of the display device may be improved.

Referring to FIG. 12, the above-described fifth light-emitting region may not form the third light-emitting region 131, but form the second light-emitting region 121. The third light-emitting region 131 may include a sixth light-emitting region surrounded by a third long side 131e, a third short side 131f, a ninth opposite side 131g, and a tenth opposite side 131h, and a seventh light-emitting region surrounded by an eleventh opposite side 131h and a twelfth opposite side 131i. The first sub-pixel pitch region SPP1 may extend in the second direction D2. Accordingly, the color reproducibility of the display panel may be enhanced, and the visibility of the display device may be improved.

FIG. 13 is a view illustrating a portion of a vehicle to which the display device according to one embodiment of the present disclosure is applied.

Referring to FIG. 13, the display device may be a vehicle display disposed at the front of the vehicle. However, embodiments of the present disclosure are not limited thereto. The display device may include a first display region DA1 disposed in front of a driver to output an image IMA1 related to vehicle safety such as vehicle speed, and a second display region DA2 disposed in front of a passenger's seat to output images IMA2 and IMA3 which may be watched by both the driver and the passenger. The second display region DA2 may have a viewing angle adjusted in left and right directions so as not to interfere with driving while driving.

The second display region DA2 may include a 2-2 display region DA22 disposed in front of the passenger's seat and a 2-1 display region DA21 disposed between the first display region DA1 and the 2-2 display region DA22. When a navigation image IMA2 is output to the 2-1 display region DA21, the 2-1 display region DA21 may operate in a first mode so that the driver may watch the navigation image. However, when an image other than the navigation image is output, the 2-1 display region DA21 may operate in a second mode. The first mode may be a mode in which a viewing angle of light output from the display panel is wide so that both the driver and the passenger may watch the image. On the other hand, the second mode may be a mode in which the viewing angle of the image output from the display panel is narrow so that the driver cannot watch the image.

The passenger may watch various content images through the 2-2 display region DA22 while driving. For example, the content images such as movies and news may be displayed on the 2-2 display region DA22. These images may distract driver's eyes while driving, and thus need to operate in the second mode so that the driver cannot watch the images.

On the other hand, the first display region DAI should convey information related to the operation of the vehicle to the driver and/or passenger and thus may always operate in the first mode.

A long side or short side of the display device may be disposed adjacent to a window WD of the vehicle. The long side may be disposed in one direction of an inner frame of the vehicle. The long side may be parallel to the window WD, and the user's line of sight when looking from the side of the display device may be perpendicular to the short side of the display device. In this case, the user may look at the display device from the steering wheel.

The display device according to one embodiment of the present disclosure may include the blocking layer 52. The blocking layer 52 may prevent an image, letters, and the like displayed on the display device from being displayed on the window WD. The blocking layer 52 may prevent light emitted from the display panel from traveling at a certain angle to the surface of the display panel. When the display device including the blocking layer 52 emits light, the driver's viewing angle may be limited and thus the image may not be displayed on the window WD, but at the same time, an afterimage or stripe (or a wave pattern) may be displayed on the display device due to the Moire phenomenon. The embodiments of the present disclosure may prevent a pattern from occurring on the display device by preventing the above-described Moire phenomenon.

According to the present disclosure, a display panel can limit a user's viewing angle by blocking light directed in a specific direction.

According to the present disclosure, the display panel can prevent a Moire phenomenon which can occur while including a blocking layer.

According to the present disclosure, the display panel can have an advantage of limiting the viewing angle while preventing the Moire phenomenon and maintaining a brightness value of the display panel.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

Example embodiments of the present disclosure may be described as follows.

In one example embodiment, a display panel including a plurality of pixels, each of the plurality of pixels comprises: a first light-emitting region that is surrounded by a first long side and a first short side parallel to each other, and a first opposite side and a second opposite side facing each other and connecting both ends of the first lone side and both ends of the first short side, and implements a first color; a second light-emitting region that is surrounded by a second long side and a second short side parallel to each other, and a third opposite side and a fourth opposite side facing each other and connecting both ends of the second lone side and both ends of the first short side, and implements a second color; a third light-emitting region that is spaced apart from the first and second light-emitting regions and implements a third color; and a plurality of light blocking patterns disposed to extend in a first direction to overlap the first to third light-emitting regions, wherein the first long side and the second long side are disposed to extend in a second direction intersecting the first direction.

In the embodiment, the first direction and the second direction may be orthogonal to each other.

In the embodiment, the display panel may further comprise a first pixel gap region formed between the second long side included in a first pixel of the plurality of pixels and the first long side included in a second pixel.

In the embodiment, the first pixel gap region may be disposed to extend in the second direction.

In the embodiment, the display panel may further comprise a first sub-pixel pitch region formed between the first short side and the second short side of the first pixel.

In the embodiment, the first sub-pixel pitch region may be disposed to extend in the second direction.

In the embodiment, the third light-emitting region may be surrounded by a fifth opposite side disposed to face the first opposite side, a sixth opposite side disposed to face the third opposite side, a seventh opposite side disposed to face the sixth opposite side, and an eighth opposite side disposed to face the fifth opposite side.

In the embodiment, the display panel may further comprise a second sub-pixel pitch region formed between the first opposite side and the fifth opposite side of the first pixel; and a third sub-pixel pitch region formed between the third opposite side and the sixth opposite side of the first pixel.

In the embodiment, the first direction and the second direction may be orthogonal to each other, the second sub-pixel pitch region may be disposed to extend in a third direction intersecting the second direction, and the third direction may intersect the second direction at an intersection angle greater than 0 degrees and less than 90 degrees.

In the embodiment, the first direction and the second direction may be orthogonal to each other, the third sub-pixel pitch region may be disposed to extend in a fourth direction intersecting the second direction, and the fourth direction may intersect the second direction at an intersection angle greater the 0 degrees and less than 90 degrees.

In the embodiment, the firth opposite side and the eighth opposite side may be parallel to each other, and the sixth opposite side and the seventh opposite side may be parallel to each other.

In the embodiment, the fifth opposite side and the first opposite side may be parallel to each other, and the sixth opposite side and the third opposite side may be parallel to each other.

In the embodiment, the seventh opposite side and the second opposite side may be parallel to each other, and the eighth opposite side and the fourth opposite side may be parallel to each other.

In the embodiment, the display panel further may comprise a second pixel gap region formed between the seventh opposite side of the first pixel and the second opposite side of a third pixel adjacent to the first and second pixels; and a third pixel gap region formed between the eighth opposite side of the first pixel and the fourth opposite side of the third pixel.

In the embodiment, the second pixel gap region may be disposed to extend in a direction parallel to the third sub-pixel pitch region, and the third pixel gap region may be disposed to extend in a direction parallel to the second sub-pixel pitch region.

In the embodiment, the light blocking pattern may include a reverse-tapered shape in a thickness direction of the display panel.

In the embodiment, the first color may be green, the second color may be red, and the third color may be blue.

As set forth above, specific example embodiments of the present disclosure have been described in more detail with reference to the accompanying drawings. However, the present disclosure is not limited to the foregoing example embodiments, but a variety of modifications are possible without departing from the principle of the present disclosure. Thus, the foregoing example embodiments disclosed herein should be interpreted as being illustrative, while not being limiting, of the principle of the present disclosure, and the scope of the present disclosure is not limited to the foregoing example embodiments. Therefore, the foregoing example embodiments should not be construed as being exhaustive in any aspects.

It will be apparent to those skilled in the art that various modifications and variations can be made in the present disclosure without departing from the spirit or scope of the disclosure. Thus, it is intended that the present disclosure cover such modifications and variations of this disclosure.

What is claimed is:

1. A display panel including a plurality of pixels, each of the plurality of pixels comprising:
a first light-emitting region that is surrounded by a first long side and a first short side that are parallel to each other, and a first opposite side and a second opposite side facing each other and connecting both ends of the first long side and both ends of the first short side, the first light-emitting region implementing a first color;
a second light-emitting region that is surrounded by a second long side and a second short side that are parallel to each other, and a third opposite side and a fourth opposite side facing each other and connecting both ends of the second long side and both ends of the first short side, the second light-emitting region implementing a second color;
a third light-emitting region that is spaced apart from the first light-emitting region and the second light-emitting region, the third light-emitting region implementing a third color; and
a plurality of light blocking patterns that extend in a first direction and overlap the first light-emitting region to the third light-emitting region,
wherein the first long side and the second long side extend in a second direction that intersects the first direction.

2. The display panel of claim 1, wherein the first direction and the second direction are orthogonal to each other.

3. The display panel of claim 1, further comprising:
a first pixel gap region between the second long side included in a first pixel of the plurality of pixels and the first long side included in a second pixel.

4. The display panel of claim 3, wherein the first pixel gap region extends in the second direction.

5. The display panel of claim 3, further comprising:
a first sub-pixel pitch region between the first short side and the second short side of the first pixel.

6. The display panel of claim 5, wherein the first sub-pixel pitch region extends in the second direction.

7. The display panel of claim 3, wherein the third light-emitting region is surrounded by a fifth opposite side that faces the first opposite side, a sixth opposite side that faces the third opposite side, a seventh opposite side that faces the sixth opposite side, and an eighth opposite side that faces the fifth opposite side.

8. The display panel of claim 7, further comprising:
a second sub-pixel pitch region between the first opposite side and the fifth opposite side of the first pixel; and
a third sub-pixel pitch region between the third opposite side and the sixth opposite side of the first pixel.

9. The display panel of claim 8, wherein:
the first direction and the second direction are orthogonal to each other;
the second sub-pixel pitch region extends in a third direction that intersects the second direction; and
the third direction intersects the second direction at an intersection angle greater than 0 degrees and less than 90 degrees.

10. The display panel of claim 8, wherein:
the first direction and the second direction are orthogonal to each other;
the third sub-pixel pitch region extends in a fourth direction that intersects the second direction; and
the fourth direction intersects the second direction at an intersection angle greater than 0 degrees and less than 90 degrees.

11. The display panel of claim 7, wherein:
the fifth opposite side and the eighth opposite side are parallel to each other; and
the sixth opposite side and the seventh opposite side are parallel to each other.

12. The display panel of claim 11, wherein:
the fifth opposite side and the first opposite side are parallel to each other; and
the sixth opposite side and the third opposite side are parallel to each other.

13. The display panel of claim 7, wherein:
the seventh opposite side and the second opposite side are parallel to each other; and
the eighth opposite side and the fourth opposite side are parallel to each other.

14. The display panel of claim 8, further comprising:
a second pixel gap region between the seventh opposite side of the first pixel and the second opposite side of a third pixel that is adjacent to the first pixel and the second pixel; and
a third pixel gap region between the eighth opposite side of the first pixel and the fourth opposite side of the third pixel.

15. The display panel of claim 14, wherein:
the second pixel gap region extends in a direction parallel to the third sub-pixel pitch region; and
the third pixel gap region extends in a direction parallel to the second sub-pixel pitch region.

16. The display panel of claim 1, wherein a light blocking pattern from the plurality of light blocking patterns includes a reverse-tapered shape in a thickness direction of the display panel.

17. The display panel of claim 1, wherein the first color is green, the second color is red, and the third color is blue.
